(19) United States
(12) Patent Application Publication
(10) Pub. No.: US 2020/0012130 A1
(43) Pub. Date: Jan. 9, 2020

(54) OPTICAL LAMINATE AND FRONT PANEL OF IMAGE DISPLAY APPARATUS, IMAGE DISPLAY APPARATUS, RESISTIVE FILM-TYPE TOUCH PANEL, AND CAPACITANCE-TYPE TOUCH PANEL HAVING OPTICAL LAMINATE

(71) Applicant: FUJIFILM Corporation, Tokyo (JP)

(72) Inventors: Takashi TAMADA, Kanagawa (JP); Keigo UEKI, Kanagawa (JP); Yuichi FUKUSHIGE, Kanagawa (JP); Katsuyuki TAKADA, Kanagawa (JP)

(73) Assignee: FUJIFILM Corporation, Tokyo (JP)

(21) Appl. No.: 16/573,360

(22) Filed: Sep. 17, 2019

Related U.S. Application Data
(63) Continuation of application No. PCT/JP2018/014367, filed on Apr. 4, 2018.

(30) Foreign Application Priority Data
Apr. 11, 2017 (JP) 2017-078487
Dec. 28, 2017 (JP) 2017-253299

(51) Int. Cl. G02F 1/1339; G02F 1/1333; H01L 27/32; H01L 51/52; G06F 3/044; G06F 3/045

(52) U.S. Cl. CPC G02F 1/1339; G02F 1/133308; G02F 1/13338; G02F 2001/133331; H01L 51/5237; G06F 3/044; G06F 3/045; H01L 27/323

(57) ABSTRACT

An optical laminate has thin glass having a thickness equal to or smaller than 120 μm and a cushioning layer which is disposed on one side of the thin glass and has a thickness equal to or greater than 5 μm, in which the cushioning layer has a peak of tan δ within a range of 10¹ to 10¹⁵ Hz at 25° C.

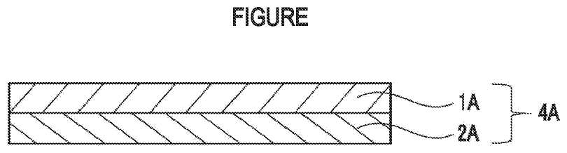

### CROSS-REFERENCE TO RELATED APPLICATIONS

This application is a Continuation of PCT International Application No. PCT/JP2018/014367, filed on Apr. 4, 2018, which was published under PCT Article 21(2) in Japanese, and which claims priority under 35 U.S.C. § 119(a) to Japanese Patent Application No. 2017-078487, filed on Apr. 11, 2017 and Japanese Patent Application No. 2017-253299, filed on Dec. 28, 2017. The above applications are hereby expressly incorporated by reference, in their entirety, into the present application.

### BACKGROUND OF THE INVENTION

### 1. Field of the Invention

The present invention relates to an optical laminate and a front panel of an image display apparatus, an image display apparatus, a resistive film-type touch panel, and a capacitance-type touch panel which have the optical laminate.

### 2. Description of the Related Art

For a front panel of an image display apparatus, particularly, a front panel of a touch panel or the like that is required to have high durability, glass such as chemically strengthened glass has been mainly used. In recent years, as a demand on lightweighting and thinning of image display apparatuses has increased, thinning of glass has been examined. However, thinning of glass leads to a problem of reduction in impact resistance.

In order to solve the problem, JP2017-024177A discloses an optical laminate comprising thin glass having a thickness equal to or smaller than 100 μm and a polarizing plate disposed on one side of the thin glass, in which the polarizing plate includes a polarizer and a protective film disposed on a surface of the polarizer that is on the thin glass side. Furthermore, JP2017-042989A discloses an optical laminate comprising thin glass having a thickness equal to or smaller than 100 μm and a conductive film disposed on one side of the thin glass, in which the conductive film includes a substrate and a conductive layer disposed on one side of the substrate.

### SUMMARY OF THE INVENTION

According to the above documents, the optical laminates prevent breakage of the thin glass and have excellent impact resistance. However, higher impact resistance is required in some cases.

The present invention has been made in consideration of the above problem, and an object of the present invention is to provide an optical laminate having higher impact resistance and a front panel of an image display apparatus, an image display apparatus, a resistive film-type touch panel, and a capacitance-type touch panel which have the optical laminate.

The object has been achieved by the following means.

(1) An optical laminate including thin glass having a thickness equal to or smaller than 120 μm and a cushioning layer which is disposed on one side of the thin glass and has a thickness equal to or greater than 5 μm, in which the cushioning layer has a peak of tan δ within a range of 10¹ to 10¹⁵ Hz at 25° C.

(2) The optical laminate described in (1), in which a storage modulus of the cushioning layer is equal to or higher than 0.1 MPa and less than 1,000 MPa.

(3) The optical laminate described in (1) or (2), in which the cushioning layer contains at least one kind of resin selected from a block copolymer of methyl methacrylate and n-butyl acrylate and a block copolymer of styrene and either or both of isoprene and butene.

(4) A front panel of an image display apparatus having the optical laminate described in any one of (1) to (3).

(5) An image display apparatus having the front panel described in (4) and an image display device.

(6) The image display apparatus described in (5) in which the image display device is a liquid crystal display device, an organic electroluminescence display device, an in-cell touch panel display device, or an on-cell touch panel display device.

(7) A resistive film-type touch panel having the front panel described in (4).

(8) A capacitance-type touch panel having the front panel described in (4).

In the present specification, a range of numerical values described using “to” means a range including numerical values listed before and after “to” as an upper limit and a lower limit respectively.

In the present specification, “(meth)acrylate” means “either or both of acrylate and methacrylate”. Furthermore, “(meth)acryloyl group” means “either or both of an acryloyl group and a methacryloyl group”, and “(meth)acryl” means “either or both of acryl and methacryl”.

Regarding each component described in the present specification, one kind of the component may be used singly, or two or more kinds of the components having different structures may be used in combination. Regarding the content of each component, in a case where two or more kinds of the components having different structures are used in combination, the content means the total content thereof.

In the present specification, the thickness of each layer can be determined by known film thickness measurement methods such as a film thickness measurement method performed using a stylus-type film thickness gauge. In a case where the film thickness is measured at a plurality of sites, the film thickness of each layer means the arithmetic mean of the film thicknesses measured at the plurality of sites.

According to the present invention, it is possible to provide an optical laminate which maintains excellent hardness of thin glass, prevents the thin glass from being easily broken, and has higher impact resistance. Furthermore, it is possible to provide a front panel of an image display apparatus, an image display apparatus, a resistive film-type touch panel, and a capacitance-type touch panel which have the optical laminate.

### BRIEF DESCRIPTION OF THE DRAWINGS

The FIGURE is a vertical cross-sectional view showing the constitution of an optical laminate according to an embodiment of the present invention.

### DESCRIPTION OF THE PREFERRED EMBODIMENTS

Preferred embodiments of the optical laminate of the present invention will be described.

[Optical Laminate]

The optical laminate according to an embodiment of the present invention comprises thin glass having a thickness equal to or smaller than 120 μm and a cushioning layer which is disposed on one side of the thin glass and has a thickness equal to or greater than 5 μm (preferably has a thickness greater than 10 μm). More specifically, in a case where the optical laminate according to the embodiment of the present invention is used as a front panel of an image display apparatus, between surfaces of the thin glass, a surface on a non-viewing side (side on which an image display device will be disposed) is provided with the cushioning layer. The cushioning layer has a peak of tan δ within a range of 10¹ to 10¹⁵ Hz at 25° C.

Because the optical laminate according to the embodiment of the present invention comprises the thin glass, hardness thereof is high. Furthermore, because the optical laminate comprises the cushioning layer, which has a predetermined thickness and predetermined characteristics, on one surface of the thin glass, the thin glass is hardly broken, and higher impact resistance can be realized.

The optical laminate according to the embodiment of the present invention may further comprise other layers. Examples of those other layers include an antireflection layer, an antiglare layer, an antistatic layer, a protective layer, and the like. Furthermore, the thin glass and the cushioning layer may be laminated through an adhesive layer.

The light transmittance of the optical laminate according to the embodiment of the present invention is preferably equal to or higher than 90%. The light transmittance can be measured using an ultraviolet-visible-near infrared spectrophotometer UV3150 manufactured by Shimadzu Corporation.

Hereinafter, the optical laminate according to the embodiment of the present invention will be specifically described.

The FIGURE is a view schematically illustrating a cross section of the optical laminate according to an embodiment of the present invention. An optical laminate 4A is an optical laminate constituted with two layers including thin glass 1A and a cushioning layer 2A disposed on one surface of the thin glass 1A. The optical laminate according to the embodiment of the present invention can have a constitution in which an adhesive layer is provided between the thin glass 1A and the cushioning layer 2A. Furthermore, the optical laminate may have an antireflection layer, a protective layer, and the like on a side (upper side in the FIGURE) of the thin glass 1A that is opposite to the cushioning layer 2A side. In addition, a protective layer and the like can be provided on a side (lower side in the FIGURE) of the cushioning layer 2A that is opposite to the thin glass 1A side.

<Thin Glass>

As long as the thin glass that the optical laminate according to the embodiment of the present invention comprises has a plate shape, materials of the thin glass are not particularly limited. In a case where the materials are classified according to composition, examples thereof include soda lime glass, borate glass, aluminosilicate glass, quartz glass, and the like. In a case where the materials are classified according to alkali components, examples thereof include alkali-free glass and low-alkali glass. The content of alkali metal components (for example, Na₂O, K₂O, and Li₂O) in the glass is preferably equal to or smaller than 15% by mass, and more preferably equal to or smaller than 10% by mass.

The thickness of the thin glass is equal to or smaller than 120 μm, and preferably equal to or smaller than 100 μm. The thickness of the thin glass may be equal to or smaller than 80 μm, equal to or smaller than 50 μm, equal to or smaller than 40 μm, or equal to or smaller than 35 μm. The lower limit of the thickness of the thin glass is preferably equal to or greater than 5 μm, more preferably equal to or greater than 20 μm, and even more preferably equal to or greater than 30 μm.

The light transmittance of the thin glass at a wavelength of 550 nm is preferably equal to or higher than 85%. The refractive index of the thin glass at a wavelength of 550 nm is preferably 1.4 to 1.65.

The density of the thin glass is preferably 2.3 g/cm³ to 3.0 g/cm³, and more preferably 2.3 g/cm³ to 2.7 g/cm³. In a case where the density of the thin glass is within the above range, a lightweight optical laminate is obtained.

The method for preparing the thin glass is not particularly limited. For example, a mixture, which contains a main material such as silica or alumina, an antifoaming agent such as mirabilite or antimony oxide, and a reducing agent such as carbon, is melted at a temperature of 1,400° C. to 1,600° C., molded in the form of a thin plate, and then cooled, thereby preparing the thin glass. Examples of methods for molding the thin glass include a slot down draw method, a fusion method, a float method, and the like. If necessary, the thin glass molded in the form of a plate by these methods may be chemically polished using a solvent such as hydrofluoric acid so as to make the thin glass into a thin plate or improve smoothness thereof.

As the thin glass, commercial products may be used as they are. Alternatively, commercial thin glass may be used after being polished to obtain a desired thickness. Examples of commercial thin glass include “7059”, “1737”, and “EAGLE2000” manufactured by Corning Incorporated. “AN100” manufactured by ACG Inc., “NA-35” manufactured by NH Techno Glass Corporation, “OA-10” manufactured by Nippon Electric Glass Co., Ltd., “D263” and “AF45” manufactured by Schott AG, and the like.

<Cushioning Layer>

In a case where the optical laminate according to the embodiment of the present invention is used as a front panel of an image display apparatus, the cushioning layer that the optical laminate comprises exhibits transparency capable of securing visibility of what is displayed and effectively prevents the thin glass from being broken due to pressure applied to the front panel, collision, and the like. The thickness of the cushioning layer used in the present invention is equal to or greater than 5 μm. From the viewpoint of fully relieving the impact exerted on the thin glass, the thickness of the cushioning layer is preferably equal to or greater than 10 μm, more preferably greater than 10 μm, and even more preferably equal to or greater than 20 μm. Furthermore, from the viewpoint of preventing deformation occurring in a case where load is applied to the thin glass, the thickness of the cushioning layer is preferably equal to or smaller than 100 μm, and more preferably equal to or smaller than 60 μm.

The cushioning layer has a peak of tan δ within a range of 10¹ to 10¹⁵ Hz at 25° C. In a case where the optical laminate according to the embodiment of the present invention is used, for example, as a front panel of a touch panel or the like, usually, the thin glass does not crack by finger pressure or a stylus pen. In contrast, in a case where a higher impact is applied thereto such as a case where the optical laminate falls on concrete or is hit with a hard object, the thin glass easily cracks. In a case where the impact resulting from the collision with a hard object is applied to the optical laminate as described above, generally, the frequency of the impact is within a certain frequency range with a frequency of about 10⁴ Hz as the center. The cushioning layer used in the present invention has a peak of tan δ within a range of 10¹ to 10¹⁵ Hz at 25° C. and is capable of effectively protecting the thin glass from the impact. At 25° C., the cushioning layer preferably has a peak of tan δ within a range of 10² to 10¹² Hz, more preferably has a peak of tan δ within a range of 10² to 10¹⁰ Hz, even more preferably has a peak of tan δ within a range of 10² to 10⁸ Hz, and particularly preferably has a peak of tan δ within a range of 10³ to 5×10⁷ Hz. In this case, at 25° C., the cushioning layer just need to have one peak of tan δ within a range of 10¹ to 10¹⁵ Hz (preferably 10² to 10¹² Hz, more preferably 10² to 10¹⁰ Hz, even more preferably 10² to 10⁸ Hz, and particularly preferably 10³ to 5×10⁷ Hz), and may have two or more peaks of tan δ within the above range. Furthermore, the cushioning layer may additionally have a peak of tan δ in a frequency range other than the above range, and the peak may be a maximum peak.

From the viewpoint of impact absorption, the peak of tan δ of the cushioning layer within a range of 10¹ to 10¹⁵ Hz (preferably 10² to 10¹² Hz, more preferably 10² to 10¹⁰ Hz, even more preferably 10² to 10⁸ Hz, and particularly preferably 10³ to 5×10⁷ Hz) at 25° C. is preferably equal to or greater than 0.1, and more preferably equal to or greater than 0.2. Furthermore, from the viewpoint of hardness, the peak is preferably equal to or smaller than 3.0.

In the present invention, regarding the frequency-tan δ relationship of the cushioning layer at 25° C., a graph of frequency-tan δ is created by the following method, and the peak of tan δ and the frequency at which the peak is found are determined. tan δ is a ratio of a loss modulus to a storage modulus.

—Method for Preparing Sample (Test Piece)—

Materials constituting the cushioning layer are dissolved or melted in a solvent, thereby obtaining a coating solution. A release-treated surface of a release PET sheet having undergone a release treatment is coated with the coating solution such that the thickness becomes 40 μm after drying. By drying the coating film, the cushioning layer is formed. By peeling the cushioning layer from the release PET sheet, a test piece of a cushioning layer is prepared.

—Measurement Method—

The test piece humidified in advance for 2 hours or longer in an atmosphere with a temperature of 25° C. and a relative humidity of 60% is measured using a viscoelasticity measurement apparatus (DVA-225 manufactured by ITS JAPAN) in a “Stepwise heating.Frequency dispersion” mode under the following conditions. Then, by “Master curve” edition, a master curve of tan δ with respect to a frequency at 25° C., a storage modulus, and a loss modulus is obtained. From the obtained master curve, a peak of tan δ and a frequency at which the peak is found are determined.

Sample: 5 mm×20 mm

Distance between grippers: 20 mm

Set stress: 0.10%

Measurement temperature: −40° C. to 40° C.

Heating condition: 2° C./min

At a frequency corresponding to a peak of tan δ of the cushioning layer within a range of 10¹ to 10¹⁵ Hz (preferably 10² to 10¹² Hz, more preferably 10² to 10¹⁰ Hz, even more preferably 10² to 10⁸ Hz, and particularly preferably 10³ to 5×10⁷ Hz) at 25° C., a storage modulus (E′) of the cushioning layer is preferably equal to or higher than 0.1 MPa and less than 1,000 MPa. E′ is more preferably equal to or higher than 30 MPa. In a case where E′ is equal to or higher than 30 MPa, it is possible to more effectively inhibit the excessive reduction of hardness. E′ is more preferably equal to or higher than 50 MPa. Furthermore, E′ is preferably equal to or lower than 800 MPa or equal to or lower than 600 MPa.

Examples of cushioning layer-forming materials constituting the cushioning layer having a peak of tan δ within a frequency range of 10¹ to 10's Hz (preferably 10² to 10¹² Hz, more preferably 10² to 10¹⁰ Hz, even more preferably 10² to 10⁸ Hz, and particularly preferably 10³ to 5×10⁷ Hz) at 25° C. include (meth)acrylate resin and an elastomer, and these can be used in combination as well.

As the elastomer, an acrylic block (co)polymer and a styrene-based block (co)polymer are preferable. Examples of the acrylic block copolymer include a block copolymer of methyl methacrylate and n-butyl acrylate (referred to as “PMMA-PnBA copolymer” as well) and the like. Examples of the styrene-based block (co)polymer include a block copolymer of styrene and either or both of isoprene and butene, and the like. By adjusting the type or copolymerization ratio of components to be copolymerized, a cushioning layer having a peak of tan δ within a desired range can be formed.

Furthermore, the cushioning layer may be constituted with a resin containing at least one kind of resin selected from a urethane-modified polyester resin and a urethane resin.

The resin or the elastomer that the cushioning layer can contain may be synthesized by general methods, or commercial products may be used as the resin or the elastomer. Examples of the commercial products include KURARITY LA1114, KURARITY LA2140E, KURARITY LA2250, KURARITY LA2330, KURARITY LA4285, HYBRAR 5127, and HYBRAR 7311F (manufactured by KURARAY CO., LTD., trade names), and the like.

From the viewpoint of balance between solubility in a solvent and hardness, the weight-average molecular weight of the resin or the elastomer is preferably 10,000 to 1,000,000, and more preferably 50,000 to 500,000.

The cushioning layer may be constituted only with a resin and/or an elastomer. Furthermore, the cushioning layer can also be constituted using a composition containing additives such as a softener, a plasticizer, a lubricant, a crosslinking agent, a crosslinking aid, a photosensitizer, an antioxidant, an antistaling agent, a heat stabilizer, a flame retardant, a fungicidal.antibacterial agent, a weathering agent, an ultraviolet absorber, a viscosity imparting agent, a nucleating agent, a pigment, a dye, an organic filler, an inorganic filler, a silane coupling agent, and a titanium coupling agent, a and a resin other than those described above.

The inorganic filler which can be added to the cushioning layer is not particularly limited. For example, it is possible to use silica particles, zirconia particles, alumina particles, mica, talc, and the like. One kind of inorganic filler can be used, or two or more kinds of inorganic fillers can be used in combination. In view of dispersion in the cushioning layer, silica particles are preferable.

The surface of the inorganic filler may be treated with a surface modifier, which has a functional group capable of being bonded to or adsorbed onto the inorganic filler, so as to improve the affinity of the inorganic filler with the resin constituting the cushioning layer. Examples of the surface modifier include a metal alkoxide surface modifier such as silane, aluminum, titanium, or zirconium, and a surface modifier having an anionic group such as a phosphoric acid group, a sulfuric acid group, a sulfonic acid group, or a carboxylic acid group.

In a case where the cushioning layer contains an inorganic filler, considering the balance between the modulus of elasticity and tan S of the cushioning layer, the content of the inorganic filler in the solid contents of the cushioning layer is preferably 1% to 40% by mass, more preferably 5% to 30% by mass, and even more preferably 5% to 15% by mass. The size (average primary particle diameter) of the inorganic filler is preferably 10 nm to 100 nm, and more preferably 15 to 60 nm. The average primary particle diameter of the inorganic filler can be determined from an electron micrograph. In a case where the particle diameter of the inorganic filler is too small, the effect of improving the modulus of elasticity is not obtained. In a case where the particle diameter of the inorganic filler is too large, sometimes haze increases. The inorganic filler may have any of a plate shape, a spherical shape, or a non-spherical shape.

Specific examples of the inorganic filler include ELECOM V-8802 (manufactured by JGC CORPORATION, spherical silica particles having an average primary particle diameter of 12 nm), ELECOM V-8803 (manufactured by JGC CORPORATION, silica particles of irregular shapes), MiBK-ST (manufactured by NISSAN CHEMICAL INDUSTRIES, LTD., spherical silica particles having an average primary particle diameter of 10 to 20 nm), MEK-AC-2140Z (manufactured by NISSAN CHEMICAL INDUSTRIES, LTD., spherical silica particles having an average primary particle diameter of 10 to 20 nm), MEK-AC-4130 (manufactured by NISSAN CHEMICAL INDUSTRIES, LTD., spherical silica particles having an average primary particle diameter of 40 to 50 nm), MIBK-SD-L (manufactured by NISSAN CHEMICAL INDUSTRIES, LTD., spherical silica particles having an average primary particle diameter of 40 to 50 nm), MEK-AC-5140Z (manufactured by NISSAN CHEMICAL INDUSTRIES, LTD., spherical silica particles having an average primary particle diameter of 70 to 100 nm), and the like.

The resin as an additive which can be added to the cushioning layer is not particularly limited. For example, it is possible to use a rosin ester resin, a hydrogenated rosin ester resin, a petrochemical resin, a hydrogenated petrochemical resin, a terpene resin, a terpene phenol resin, an aromatic modified terpene resin, a hydrogenated terpene resin, an alkyl phenol resin, and the like. One kind of each of these may be used singly, or two or more kinds of these may be used in combination.

Considering the balance between the storage modulus and tan S of the cushioning layer, the content of the additives in the solid contents of the cushioning layer is preferably 1% to 40% by mass, more preferably 5% to 30% by mass, and even more preferably 5% to 15% by mass.

Specific examples of the additives include SUPER ESTER A75, SUPER ESTER A115, and SUPER ESTER A125 (manufactured by Arakawa Chemical Industries, Ltd., rosin ester resins), PETROTAC 60, PETROTAC 70, PETROTAC 90, PETROTAC 100, PETROTAC 100V, and PETROTAC 90HM (manufactured by Tosoh Corporation, petrochemical resins), YS POLYSTER T30, YS POLYSTER T80, YS POLYSTER T100, YS POLYSTER T115, YS POLYSTER T130, YS POLYSTER T145, and YS POLYSTER T160 (manufactured by YASUHARA CHEMICAL CO., LTD., terpene phenol resins), and the like.

<Method for Preparing Optical Laminate>

The method for forming the cushioning layer is not particularly limited, and examples thereof include a coating method, a casting method (a solventless casting method or a solvent casting method), a press method, an extrusion method, an injection molding method, a cast molding method, an inflation method, and the like. Specifically, by steps of preparing a liquid substance, in which the aforementioned material constituting the cushioning layer (cushioning material) is dissolved or dispersed, or a melt of components constituting the aforementioned cushioning material, then coating thin glass with the liquid substance or the melt, and then removing the solvent if necessary, and the like, an optical laminate in which the cushioning layer is laminated can be prepared.

Furthermore, by coating a release-treated surface of a release sheet having undergone a release treatment with the cushioning material, drying the cushioning material so as to form a sheet having a cushioning layer, and bonding the cushioning layer of this sheet to thin glass, an optical laminate in which the cushioning layer is laminated can be prepared.

The cushioning layer may have a crosslinked structure, or some of the constituent materials thereof may be crosslinked. The method for crosslinking the cushioning material is not particularly limited, and examples thereof include means selected from methods using electron beam irradiation, ultraviolet irradiation, and a crosslinking agent (for example, an organic peroxide or the like). In a case where the resin is crosslinked by electron beam irradiation, by irradiating the obtained cushioning layer (not yet being crosslinked) with electron beams from an electron beam irradiation apparatus, crosslinks can be formed. In the case of ultraviolet irradiation, by irradiating the obtained cushioning layer (not yet being crosslinked) with ultraviolet rays from an ultraviolet irradiation apparatus, crosslinks can be formed by the effect of a photosensitizer which is optionally mixed in. Furthermore, in a case where a crosslinking agent is used, generally, by heating the obtained cushioning layer (not yet being crosslinked) in an anaerobic atmosphere such as a nitrogen atmosphere, crosslinks can be formed by the crosslinking agent such as an organic peroxide optionally mixed and a crosslinking aid.

In the present invention, it is more preferable that the cushioning layer does not have a crosslinked structure.

In view of cushioning properties, the film thickness of the cushioning layer is preferably equal to or greater than 5 μm, more preferably greater than 10 μm, and even more preferably equal to or greater than 20 μm. The upper limit thereof is substantially equal to or smaller than 100 μm, and preferably equal to or smaller than 80 μm or equal to or smaller than 60 μm.

<Other Layers>

—Adhesive Layer—

The cushioning layer may be disposed on one side of thin glass through an adhesive layer. It is preferable that the adhesive layer is formed using a composition containing a component (adhesive) expressing adhesiveness through drying or a reaction. For example, an adhesive layer formed using a composition containing a component expressing adhesiveness through a curing reaction (hereinafter, referred to as “curable composition” in some cases) is a cured layer formed by curing the curable composition.

As the adhesive, a resin can be used. In an aspect, the adhesive layer can be a layer in which a proportion of the resin in the layer is equal to or higher than 50% by mass and preferably equal to or higher than 70% by mass. As the resin, a single resin or a mixture of a plurality of resins may be used. In a case where the resin mixture is used, the aforementioned proportion of the resin refers to the proportion of the resin mixture. Examples of the resin mixture include a mixture of a certain resin and a resin having a structure established by partially modifying the certain resin, a resin mixture obtained by reacting different polymerizable compounds, and the like.

As the adhesive, it is possible to use any adhesive having appropriate properties, form, and adhesion mechanism. Specifically, examples of the adhesive include a water-soluble adhesive, an ultraviolet curable type adhesive, an emulsion-type adhesive, a latex-type adhesive, a mastic adhesive, a multi-layered adhesive, a paste-like adhesive, a foaming adhesive, a supported film adhesive, a thermoplastic adhesive, a hot-melt adhesive, a thermally solidified adhesive, a thermally activated adhesive, a heat-seal adhesive, a thermosetting adhesive, a contact-type adhesive, a pressure-sensitive adhesive, a polymerizable adhesive, a solvent-type adhesive, a solvent-activated adhesive, and the like. As the adhesive, a water-soluble adhesive and an ultraviolet curable type adhesive are preferable. Among these, a water-soluble adhesive is preferably used, because this adhesive is excellent in transparency, adhesiveness, workability, product quality, and economic feasibility.

The water-soluble adhesive can contain a natural or synthetic water-soluble component such as a protein, starch, or a synthetic resin. Examples of the synthetic resin include a resol resin, a urea resin, a melamine resin, a polyethylene oxide resin, a polyacrylamide resin, a polyvinyl pyrrolidone resin, a polyacrylic acid ester resin, a polymethacrylic acid ester resin, a polyvinyl alcohol resin, a polyacrylic resin, and a cellulose derivative (cellulose compound). Among these, a water-soluble adhesive containing a polyvinyl alcohol resin or a cellulose derivative is preferable, because this adhesive exhibits excellent adhesiveness at the time of bonding the resin films to each other. That is, it is preferable that the adhesive layer contains a polyvinyl alcohol resin or a cellulose derivative.

In view of bonding the thin glass and the cushioning layer to each other, the thickness of the adhesive layer is preferably equal to or greater than 10 nm, and more preferably 50 nm to 50 μm.

The adhesive layer can be formed by, for example, coating at least one surface of the thin glass or the cushioning layer with a coating solution containing an adhesive and then drying the coating solution. As the method for preparing the coating solution, any of appropriate methods can be adopted. As the coating solution, for example, a commercial solution or dispersion liquid, a coating solution obtained by adding a solvent to a commercial solution or dispersion liquid, or a coating solution obtained by dissolving or dispersing solid contents in various solvents may be used.

—Protective Film of Cushioning Layer—

In the optical laminate according to the embodiment of the present invention, it is preferable that a peelable protective film layer is provided on a surface of the cushioning layer that is opposite to the thin glass. In a case where the optical laminate has the protective film layer, it is possible to prevent the damage of the cushioning layer included in the optical laminate before use and prevent dirt, contaminants, and the like from adhering to the cushioning layer. At the time of use, the protective film layer can be peeled off.

In order to make it easy to peel the protective film layer, a release layer can be provided between the protective film layer and the cushioning layer. The method for providing the release layer is not particularly limited. For example, the release layer can be provided by coating the surface of at least any of the protective film layer or the cushioning layer with a release coating agent. The type of the release coating agent is not particularly limited, and examples thereof include a silicon-based coating agent, an inorganic coating agent, a fluorine-based coating agent, an organic-inorganic hybrid coating agent, and the like.

Generally, the optical laminate comprising the protective film and the release layer can be obtained by providing the release layer on the surface of the protective film layer and then laminating the resulting film on the surface of the cushioning layer. In this case, the release layer may be provided not on the surface of the protective film layer but on the surface of the cushioning layer.

—Protective Film of Thin Glass—

The optical laminate according to the embodiment of the present invention may further comprise a resin film on a side of the thin glass that is opposite to the cushioning layer. In an embodiment, the resin film is a protective film which is peelably laminated (for example, the resin film is laminated through a certain appropriate pressure sensitive adhesive layer) and protects the thin glass until the optical laminate according to the embodiment of the present invention is used.

The materials constituting the protective film of the thin glass are not particularly limited, and examples thereof include a thermoplastic resin and a curable resin cured by heat or active energy rays. Among these, a thermoplastic resin is preferable. Specifically, examples of the thermoplastic resin include a poly(meth)acrylate-based resin, a polycarbonate-based resin, a polyethylene-based resin, a polypropylene-based resin, a polystyrene-based resin, a polyamide-based resin, a polyethylene terephthalate-based resin, a polyarylate-based resin, a polyimide-based resin, a polysulfone-based resin, a cycloolefin-based resin, and the like. Among these, a poly(meth)acrylate-based resin is preferable, a polymethacrylate-based resin is more preferable, and a polymethyl methacrylate-based resin is particularly preferable. In a case where the protective film contains a polymethyl methacrylate-based resin, the thin glass can be more effectively protected. For example, even though an object with a sharp point falls on the thin glass, the occurrence of cracks, holes, and the like can be prevented.

The thickness of the protective film of the thin glass is preferably 20 μm to 1,900 μm, more preferably 50 μm to 1,500 μm, even more preferably 50 μm to 1,000 μm, and particularly preferably 50 μm to 100 μm.

The protective film of the thin glass may contain additives according to the purpose. Examples of additives used in the protective film include a diluent, an antistaling agent, a denaturant, a surfactant, a dye, a pigment, an anti-tarnishing agent, an ultraviolet absorber, a softener, a stabilizer, a plasticizer, an antifoaming agent, a stiffener, and the like. The type and amount of the additives are appropriately set according to the purpose.

—Antireflection Layer—

The optical laminate according to the embodiment of the present invention may further comprise an antireflection layer. The antireflection layer can be disposed on a side of the thin glass that is opposite to the cushioning layer.

Any of appropriate constitutions can be adopted for the antireflection layer as long as the antireflection layer has an antireflection function. It is preferable that the antireflection layer is a layer constituted with an inorganic material.

Examples of materials constituting the antireflection layer include titanium oxide, zirconium oxide, silicon oxide, magnesium fluoride, and the like. In an embodiment, as the antireflection layer, a laminate obtained by alternately laminating titanium oxide layers and silicon oxide layers is used. This laminate has an excellent antireflection function.

[Articles Having Optical Laminate]

Examples of articles including the optical laminate according to the embodiment of the present invention include various articles required to have improved impact resistance in various industrial fields such as the field of home appliances and the field of electricity and electronics. Specifically, examples of such articles include a touch sensor, a touch panel, an image display apparatus such as a liquid crystal display, and the like. By providing the optical laminate according to the embodiment of the present invention preferably as a surface protect film in these articles, it is possible to provide articles excellent in hardness and impact resistance. The optical laminate according to the embodiment of the present invention is preferably used as an optical film used in a front panel of an image display apparatus, and more preferably used as an optical film used in a front panel of an image display device of a touch panel.

The touch panel in which the optical laminate according to the embodiment of the present invention can be used is not particularly limited, and can be appropriately selected according to the purpose. Examples of the touch panel include a surface capacitance-type touch panel, a projected capacitance-type touch panel, a resistive film-type touch panel, and the like. The details of the touch panel will be described later.

The touch panel includes a so-called touch sensor. In the touch panel, the layer constitution of a touch panel sensor-electrode portion may be established by any of a bonding method in which two sheets of transparent electrodes are bonded to each other, a method of providing a transparent electrode on both surfaces of one sheet of substrate, a method using a single-face jumper or a through hole, or a single-face lamination method.

<Image Display Apparatus>

The image display apparatus having the optical laminate according to the embodiment of the present invention is an image display apparatus including a front panel having the optical laminate according to the embodiment of the present invention and an image display device.

Examples of the image display apparatus include a Liquid Crystal Display (LCD), a plasma display panel, an electroluminescent display, a cathode tube display, and a touch panel.

The liquid crystal display is constituted with a liquid crystal cell and a polarizing plate provided on a viewing side of the liquid crystal cell (front side) and on a backlight side (rear side). Examples of the liquid crystal display include a Twisted Nematic (TN) type, a Super-Twisted Nematic (STN) type, a Triple Super Twisted Nematic (TSTN) type, a multi domain type, a Vertical Alignment (VA) type, an In Plane Switching (IPS) type, an Optically Compensated Bend (OCB) type, and the like.

It is preferable that the image display apparatus has ameliorated brittleness and excellent handleability, does not impair display quality by surface smoothness or wrinkles, and can suppress the leakage of light at the time of a moisture-heat test.

That is, the image display apparatus having the optical laminate according to the embodiment of the present invention preferably includes a liquid crystal display as an image display device. Examples of the image display apparatus having a liquid crystal display include Xperia P manufactured by Sony Ericsson Mobile, and the like.

It is also preferable that the image display apparatus having the optical laminate according to the embodiment of the present invention has an organic Electroluminescence (EL) display device as an image display device.

For the organic electroluminescence display device, known techniques can be adopted without any limitation. Examples of the image display apparatus having an organic electroluminescence display device include GALAXY SII manufactured by SAMSUNG ELECTRONICS CO., LTD., and the like.

It is also preferable that the image display apparatus having the optical laminate according to the embodiment of the present invention has an In-Cell touch panel display device as an image display device. The in-cell touch panel display device is a device in which the touch panel function is built in the cell of the image display device.

For the in-cell touch panel display device, for example, known techniques described in JP2011-076602A, JP2011-222009A, and the like can be adopted without any limitation. Examples of the image display apparatus having the in-cell touch panel display device include Xperia P manufactured by Sony Ericsson Mobile, and the like.

It is also preferable that the image display apparatus having the optical laminate according to the embodiment of the present invention has an On-Cell touch panel display device as an image display device. The on-cell touch panel display device is a device in which the touch panel function is built on the outside of the cell of the image display device.

For the on-cell touch panel display device, for example, known techniques described in JP2012-088683A and the like can be adopted without any limitation. Examples of the image display apparatus having the on-cell touch panel display device include GALAXY SII manufactured by SAMSUNG ELECTRONICS CO., LTD., and the like.

<Touch Panel>

The touch panel having the optical laminate according to the embodiment of the present invention is a touch panel including a touch sensor obtained by bonding a touch sensor film to a surface, which is opposite to the thin glass, of the cushioning layer included in the optical laminate according to the embodiment of the present invention.

The touch sensor film is not particularly limited, but is preferably a conductive film in which a conductive layer is formed. The conductive film is preferably a conductive film obtained by forming a conductive layer on any support.

The material of the conductive layer is not particularly limited, and examples thereof include indium.tin composite oxide (Indium Tin Oxide; ITO), tin oxide, antimony.tin composite oxide (Antimony Tin Oxide; ATO), copper, silver, aluminum, nickel, chromium, an alloy of these, and the like. It is preferable that the conductive layer is an electrode pattern. Furthermore, it is preferable that the conductive layer is a transparent electrode pattern. The electrode pattern may be obtained by patterning a transparent conductive material layer or obtained by forming a layer of non-transparent conductive material by patterning.

—Resistive Film-Type Touch Panel—

The resistive film-type touch panel having the optical laminate according to the embodiment of the present invention is a resistive film-type touch panel which has the front panel having the optical laminate according to the embodiment of the present invention.

Basically, the resistive film-type touch panel has a constitution in which conductive films including a pair of upper and lower substrates each having a conductive film are disposed with a spacer therebetween such that the conductive films face each other. The constitution of the resistive film-type touch panel is known, and in the present invention, known techniques can be applied without any limitation.

—Capacitance-Type Touch Panel—

The capacitance-type touch panel having the optical laminate according to the embodiment of the present invention is a capacitance-type touch panel which has the front panel having the optical laminate according to the embodiment of the present invention.

Examples of the capacitance-type touch panel include a surface capacitance-type touch panel and a projected capacitance-type touch panel. The projected capacitance-type touch panel has a basic constitution in which an X-axis electrode and a Y-axis electrode orthogonal to the X-axis electrode are disposed having an insulator therebetween. Specific aspects thereof include an aspect in which the X-axis electrode and the Y-axis electrode are formed on each surface of one substrate, an aspect in which the X-axis electrode, the insulating layer, and the Y-axis electrode are formed in this order on one substrate, an aspect in which the X-axis electrode is formed on one substrate and the Y-axis electrode is formed on the other substrate (in this aspect, a constitution in which two substrates are bonded to each other is the aforementioned basic constitution), and the like. The constitution of the capacitance-type touch panel is known, and in the present invention, known techniques can be adopted without any limitation.

### EXAMPLES

Hereinafter, the present invention will be more specifically described based on examples, but the present invention is not limited thereto. In the following examples, unless otherwise specified, “part” and “%” showing a composition are based on mass.

### Examples 1 to 14 and Comparative Examples 1 to 8

By laminating a cushioning layer and thin glass, optical laminates of Examples 1 to 14 and Comparative Examples 1 to 8 were prepared. Details of the procedure will be described below.

<Preparation of Composition for Forming Cushioning Layer (CU Layer)>

Components were mixed together according to the composition shown in Table 1 and filtered through a filter made of polypropylene having a pore size of 10 μm, thereby preparing compositions CU-1 to CU-13 for forming a CU layer.

TABLE 1

| | | Composition for forming CU layer | | | | | | | | | | | | |
|---|---|---|---|---|---|---|---|---|---|---|---|---|---|---|
| | | CU-1 | CU-2 | CU-3 | CU-4 | CU-5 | CU-6 | CU-7 | CU-8 | CU-9 | CU-10 | CU-11 | CU-12 | CU-13 |
| Resin/ | CLARITY LA2250 | 100% | | | | | | | | | | | | |
| elastomer | CLARITY LA2140E | | 100% | 90% | 95% | | | | | | | | | |
| | HYBRAR 7311F | | | | | 100% | | | | | | | | |
| | VYLON UR-6100 | | | | | | 100% | | | | | | | |
| | KURAPRENE UC-203M | | | | | | | | | | | 87% | 67% | 47% |
| | CELLOXIDE 2021P | | | | | | | | | 78% | | | | |
| | ARON OXETANE OXT- | | | | | | | | | 19% | | | | |
| | 221 | | | | | | | | | | | | | |
| | Synthesis Example 1 | | | | | | | 31% | | | | | | |
| | (fluorine olefin/vinyl | | | | | | | | | | | | | |
| | alcohol copolymer) | | | | | | | | | | | | | |
| | DIANAL BR88 | | | | | | | | 100% | | | | | |
| | NK Oligo UA-122P | | | | | | | | | | 97% | | | |
| | DPHA | | | | | | | | | | | | 20% | 40% |
| Inorganic | MIBK-ST | | | | 5% | | | | | | | | | |
| filler | | | | | | | | | | | | | | |
| Additive | SUPER ESTER A115 | | | 10% | | | | | | | | | | |
| | CLEARON P150 | | | | | | | | | | | 10% | 10% | 10% |
| | ADEKA OPTOMER SP- | | | | | | | | | 3% | | | | |
| | 170 | | | | | | | | | | | | | |
| | MS51 | | | | | | | 31% | | | | | | |
| | Organosilica sol | | | | | | | 31% | | | | | | |
| | D-20 | | | | | | | 2% | | | | | | |
| | Hexamethyl trisilazane | | | | | | | 5% | | | | | | |
| | IRGACURE184 | | | | | | | | | | 3% | 3% | 3% | 3% |
| Solvent | MIBK | 100% | 100% | 100% | 100% | | | | | | 100% | | | |
| | Toluene | | | | | 100% | | | | | | 100% | 100% | 100% |
| | Propylene glycol | | | | | | | 57% | | | | | | |
| | monomethyl ether | | | | | | | | | | | | | |
| | IPA | | | | | | | 43% | | | | | | |
| | Dichloromethane | | | | | | | | 82% | | | | | |
| | Methanol | | | | | | | | 18% | | | | | |

Details of the materials described in Table 1 will be shown below.

<Resin/elastomer>
KURARITY LA2250: manufactured by KURARAY CO., LTD., PMMA-PnBA copolymer elastomer
KURARITY LA2140E: manufactured by KURARAY CO., LTD., PMMA-PnBA copolymer elastomer
HYBRAR 7311F: manufactured by KURARAY CO., LTD., polystyrene-hydrogenated isoprene copolymer elastomer
KURAPRENE UC-203M: manufactured by KURARAY CO., LTD., polymerizable group-containing polyisoprene
VYLON UR-6100: manufactured by Toyobo Co., Ltd, 45% diluted solution of polyester urethane resin (composition of dilution solvents: cyclohexanone:SOLVESSO 150:isophorone=40:40:20 (mass ratio))
CELLOXIDE 2021P: manufactured by Daicel Corporation, 3′,4′-epoxycyclohexylmethyl-3,4-epoxycyclohexane carboxylate
ARON OXETANE OXT-221: manufactured by TOAGOSEI CO., LTD., 3-ethyl-3 {[(3-ethyloxetan-3-yemethoxy]methyl}oxetane
Synthesis Example 1: synthesized by the method described in paragraph “0086” in JP2014-210421A.
DIANAL BR88: manufactured by Mitsubishi Rayon Co., Ltd., PMMA resin
NKOLIGO UA-122P: manufactured by SHIN-NAKAMURA CHEMICAL CO., LTD., ultraviolet-cured monomer
DPHA: mixture of dipentaerythritol pentaacrylate and pentaerythritol hexaacrylate (manufactured by Nippon Kayaku Co., Ltd., trade name: KAYARAD DPHA)

<Inorganic Filler>
MIBK-ST: manufactured by NISSAN CHEMICAL INDUSTRIES, LTD., spherical silica particles having average particle diameter of 10 to 20 nm.

<Additive>
SUPER ESTER A115: manufactured by Arakawa Chemical Industries, Ltd., rosin ester
CLEARON P150: manufactured by YASUHARA CHEMICAL CO., LTD., hydrogenated terpene
ADEKA OPTOMER SP-170: manufactured by ADEKA CORPORATION, sulfonium salt-based photocationic polymerization initiator
MS51: manufactured by Tama Chemicals Co., Ltd., methyl silicate oligomer
Organosilica sol: manufactured by NISSAN CHEMICAL INDUSTRIES, LTD., 30% IPA dilution solution
D-20: manufactured by Shin-Etsu Chemical Co., Ltd., titanate compound
IRGACURE 184: photopolymerization initiator manufactured by BASF SE

<Solvent>
MIBK: methyl isobutyl ketone
IPA: isopropyl alcohol

### Example 1

A surface of thin glass (8 cm (length)×8 cm (width)×100 μm (depth)) was coated with the composition CU-1 for forming a CU layer and then dried, thereby forming a CU layer.

Specifically, coating and drying were performed by the following method. By a die coating method using a slot die described in Example 1 in JP2006-122889A, the surface of the thin glass was coated with the composition for forming a CU layer under the condition of a transport speed of 30 m/min such that the film thickness became 20 μm after drying. Thereafter, the applied composition was dried for 150 seconds at an atmospheric temperature of 60° C., thereby preparing an optical laminate of Example 1.

### Examples 2, 4, 5, and 8

Optical laminates of Examples 2, 4, 5, and 8 were prepared in the same manner as in Example 1, except that compositions CU-2, CU-3, CU-4, and CU-5 forming a CU layer were used instead of the composition CU-1 for forming a CU layer.

### Example 3

An optical laminate of Example 3 was prepared in the same manner as in Example 2, except that the thickness of the thin glass was changed to 50 μm.

### Example 6

An optical laminate of Example 6 was prepared in the same manner as in Example 5, except that the film thickness of the composition for forming a CU layer was changed to 5 μm.

### Example 7

An optical laminate of Example 7 was prepared in the same manner as in Example 5, except that the film thickness of the composition for forming a CU layer was changed to 40 μm.

### Example 9

An optical laminate of Example 9 was prepared in the same manner as in Example 1, except that a composition CU-6 for forming a CU layer was used instead of the composition CU-1 for forming a CU layer, and the film thickness of the composition for forming a CU layer was changed to 40 μm.

### Example 10

—Preparation of CU Layer Sheet—

A release-treated surface of a release sheet (manufactured by Lintec Corporation, trade name: SP-PET3811), which was obtained by performing a release treatment on one surface of a polyethylene terephthalate film by using a silicone-based release agent, was coated with the composition CU-2 for forming a CU layer prepared as above such that the thickness became 20 μm after drying. The applied composition was heated for 150 seconds at an atmospheric temperature of 60° C., thereby forming a CU layer CU-2. The CU layer CU-2 was bonded to a release-treated surface of another release sheet (manufactured by Lintec Corporation, trade name: SP-PET3801), which was obtained by performing a release treatment on one surface of a polyethylene terephthalate film by using a silicone-based release agent, such that release sheet/CU layer CU-2/release sheet were laminated in this order, thereby preparing a Cu layer sheet CU-2.

—Preparation of Optical Laminate—

By using a pipette, a surface of thin glass (thickness: 100 μm) was coated with a composition CU-9 for forming a CU layer in the form of lines. Then, the thin glass and the Cu layer sheet CU-2 were bonded to each other through the aforementioned adhesive composition. The bonding was performed between rolls by using a laminator.

Thereafter, the Cu layer sheet CU-2 side of the obtained laminate was irradiated with ultraviolet rays (irradiation intensity: 50 mw/cm², irradiation time: 30 seconds) such that the composition CU-9 for forming a CU layer was semi-cured. For the ultraviolet irradiation, a high-pressure mercury lamp was used. Subsequently, the laminate was heated in an oven for 60 minutes at a temperature of 80° C. such that the composition CU-9 for forming a CU layer was fully cured, thereby preparing an optical laminate of Example 10. The layer of CU-9 was present as an adhesive layer and had a thickness of 5 μm.

### Example 11

The CU layer sheet CU-2 prepared as above was bonded to a surface of thin glass (thickness: 100 μm) through a pressure sensitive adhesive (manufactured by Soken Chemical & Engineering Co., Ltd., trade name: SK-2057) having a thickness of 20 μm in a state where a load of 2 kg was being applied thereto by a rubber roller. In this way, an optical laminate of Example 11 was prepared.

### Example 12

A surface of thin glass (8 cm (length)×8 cm (width)×100 μm (thickness)) was coated with a composition CU-11 for forming a CU layer and then dried, thereby forming a CU layer.

Specifically, coating and curing were performed by the following method. By a die coating method using a slot die described in Example 1 in JP2006-122889A, the surface of the thin glass was coated with the composition for forming a CU layer under the condition of a transport speed of 30 m/min such that the film thickness became 20 μm after drying. Then, the applied composition was dried for 150 seconds at an atmospheric temperature of 60° C. Subsequently, while nitrogen purging was being performed, by using a 160 W/cm² air-cooled metal halide lamp (manufactured by EYE GRAPHICS Co., Ltd.), the applied composition was irradiated with ultraviolet rays at an oxygen concentration of about 0.1% by volume, an illuminance of 300 mW/cm², and an irradiation amount of 600 mJ/cm², such that the applied curable composition for forming a CU layer was cured, thereby preparing an optical laminate of Example 12.

### Examples 13 and 14

Optical laminates of Examples 13 and 14 were prepared in the same manner as in Example 12, except that compositions CU-12 and CU-13 for forming a CU layer were used instead of the composition CU-11 for forming a CU layer.

### Comparative Example 1

A surface of thin glass (thickness: 100 μm) was coated with a composition CU-7 for forming a CU layer such that the film thickness became 15 μm after drying. Then, the applied composition was dried for 30 minutes at an atmospheric temperature of 50° C., for 2 hours at an atmospheric temperature of 70° C., and then for 1 hour at an atmospheric temperature of 100° C., thereby preparing an optical laminate of Comparative Example 1.

### Comparative Example 2

A surface of thin glass (thickness: 100 μm) was coated with a composition CU-8 for forming a CU layer such that the film thickness of the applied composition for forming a CU layer became 75 μm after drying. Then, the composition was dried for 6 minutes at an atmospheric temperature of 70° C. and then for 40 minutes at an atmospheric temperature of 140° C., thereby preparing an optical laminate of Comparative Example 2.

### Comparative Example 3

An optical laminate of Comparative Example 3 was prepared in the same manner as in Example 10, except that the CU layer sheet CU-2 was not bonded.

### Comparative Example 4

An optical laminate of Comparative Example 4 was prepared in the same manner as in Example 10, except that an acrylic resin sheet (manufactured by Mitsubishi Chemical Corporation, trade name “ACRIPRENE HBS010P”, thickness: 75 μm) was used instead of the CU layer sheet CU-2.

### Comparative Example 5

An optical laminate of Comparative Example 5 was prepared in the same manner as in Example 10, except that a cycloolefin-based resin sheet (manufactured by ZEON CORPORATION, trade name “ZEONOR FILM ZF16”, thickness: 100 μm) was used instead of CU-2 as a sheet of the composition for forming a CU layer.

### Comparative Example 6

By using a wire bar coater, a surface of thin glass (thickness: 100 μm) was coated with a composition CU-10 for forming a CU layer such that the film thickness became 8 μm after curing. Then, the applied composition was dried for 150 seconds at an atmospheric temperature of 60° C. such that the solvent was removed. Furthermore, the composition was irradiated with a high-pressure mercury lamp (160 W/cm²), thereby preparing an optical laminate of Comparative Example 6.

### Comparative Example 7

An optical laminate of Comparative Example 7 was prepared in the same manner as in Example 5, except that the film thickness of the composition for forming a CU layer was changed to 1 μm.

### Comparative Example 8

An optical film of Comparative Example 8 was prepared in the same manner as in Example 1, except that a layer formed of a composition for forming a CU layer was not provided.

### [Test Example] Cushioning Property Test

A glass plate (manufactured by Corning Incorporated, trade name: EAGLE XG, thickness: 0.4 mm, 10 cm (length)×10 cm (width)) and each of the optical laminates (Examples 1 to 11 and Comparative Examples 1 to 7) and the thin glass (Comparative Example 8) prepared as above were bonded to each other through a pressure sensitive adhesive having a thickness of 20 μm (manufactured by Soken Chemical & Engineering Co., Ltd., trade name: SK-2057) by using a rubber roller under a load of 2 kg applied thereto such that a surface of the CU layer that was opposite to the thin glass side and the glass plate faced each other. Then, the glass plate bonded to the optical laminate was installed on a base formed of stainless steel such that a spacer made of TEFLON (registered trademark) having a thickness of 20 mm and a width of 5 mm (a spacer of a shape obtained by punching the central portion of a 10 cm×10 cm spacer in a size of 9 cm×9 cm) was interposed between the glass plate and the stainless steel base. Thereafter, an iron ball (diameter: 3.2 cm, mass: 130 g) was allowed to fall from a predetermined height such that the iron ball contacted and collided with the thin glass of the optical laminate or the thin glass. Subsequently, the thin glass was observed. Among the heights from which the iron ball fell and did not result in observable fissures, cracks, and the like, the greatest height was adopted as an impact resistance height (cm).

The results are shown in Table 2.

TABLE 2

| | Glass | Cushioning layer | | Frequency at peak | | Storage modulus | Cushioning | Total light |
|---|---|---|---|---|---|---|---|---|
| | thickness | | Thickness | of tan δ | Peak of | (25° C.) | height | transmittance |
| | μm | Constitution | μm | (Hz) | tan δ | Mpa | Cm | % |
| Example 1 | 100 | CU1 | 20 | 2.8 × 10⁷ | 0.5 | 400 | 15 | 93 |
| Example 2 | 100 | CU2 | 20 | 1.6 × 10⁷ | 1.4 | 40 | 20 | 93 |
| Example 3 | 50 | CU2 | 20 | 1.6 × 10⁷ | 1.4 | 40 | 15 | 93 |
| Example 4 | 100 | CU3 | 20 | 1.1 × 10⁵ | 1.6 | 20 | 20 | 93 |
| Example 5 | 100 | CU4 | 20 | 1.6 × 10⁷ | 1.3 | 60 | 20 | 93 |
| Example 6 | 100 | CU4 | 5 | 1.6 × 10⁷ | 1.3 | 60 | 10 | 93 |
| Example 7 | 100 | CU4 | 40 | 1.6 × 10⁷ | 1.3 | 60 | 25 | 93 |
| Example 8 | 100 | CU5 | 20 | 3.1 × 10³ | 2.2 | 210 | 25 | 93 |
| Example 9 | 100 | CU6 | 40 | 1.0 × 10⁶ | 0.1 | 3,200 | 10 | 93 |
| Example 10 | 100 | CU2 + CU9 | 20 + 5 | 1.5 × 10⁴ | 1.4 | 40 | 20 | 93 |
| Example 11 | 100 | CU2 + Adhesive | 20 + 20 | 1.4 × 10⁷ | 1.4 | 40 | 20 | 93 |
| Example 12 | 100 | CU11 | 20 | 2.5 × 10⁵ | 2.4 | 10 | 20 | 93 |
| Example 13 | 100 | CU12 | 20 | 7.0 × 10⁴ | 1.9 | 30 | 15 | 93 |
| Example 14 | 100 | CU13 | 20 | 2.0 × 10⁴ | 1.2 | 70 | 10 | 92 |
| Comparative Example 1 | 100 | CU7 | 15 | 1.4 × 10⁻² | 0.1 | 1,000 | 5 | 91 |
| Comparative Example 2 | 100 | CU8 | 75 | 8.2 × 10⁻⁸ | 1.7 | 3,340 | 5 | 91 |
| Comparative Example 3 | 100 | CU9 | 5 | 9.1 × 10⁻¹ | 0.5 | 1,300 | 5 | 90 |
| Comparative Example 4 | 100 | Film + CU9 | 75 + 5 | 7.8 × 10⁻⁸ | 1.6 | 3,150 | 5 | 90 |
| Comparative Example 5 | 100 | Film + CU9 | 100 + 5 | 3.3 × 10⁻¹⁰ | 2.8 | 2,100 | 5 | 90 |
| Comparative Example 6 | 100 | CU10 | 8 | 6.0 × 10⁻⁴ | 1.5 | 1,500 | 5 | 93 |
| Comparative Example 7 | 100 | CU4 | 1 | 1.6 × 10⁷ | 1.3 | 60 | 5 | 93 |
| Comparative Example 8 | 100 | N/A | — | — | — | — | 5 | 93 |

As shown in Table 2, in a case where the cushioning layer has does not have a peak of tan δ within a range of 10¹ to 10¹⁵ Hz, even though the thickness of the cushioning layer is increased, the cushioning properties of the optical laminate become poor, and fissures and cracks easily occur in all of the optical laminates as in the thin glass without a cushioning layer

### Comparative Examples 1 to 6 and 8

Furthermore, even though the cushioning layer has a peak of tan δ within a range of 10¹ to 10¹⁵ Hz, in a case where the thickness of the cushioning layer is insufficient, the cushioning properties become poor (Comparative Example 7).

In contrast, all of the optical laminates, which include a cushioning layer having a peak of tan δ within a range of 10¹ to 10¹⁵ Hz and having a thickness equal to or greater than 5 μm, have excellent cushioning properties (Examples 1 to 14).

### Explanation of References

1A: thin glass
2A: cushioning layer
4A: optical laminate

What is claimed is:

1. An optical laminate comprising:
thin glass having a thickness equal to or smaller than 120 μm; and
a cushioning layer which is disposed on one side of the thin glass and has a thickness equal to or greater than 5 μm,
wherein the cushioning layer has a peak of tan δ within a range of 10¹ to 10¹⁵ Hz at 25° C.

2. The optical laminate according to claim 1,
wherein a storage modulus of the cushioning layer is equal to or higher than 0.1 MPa and less than 1,000 MPa.

3. The optical laminate according to claim 1,
wherein the cushioning layer contains at least one kind of resin selected from a block copolymer of methyl methacrylate and n-butyl acrylate and a block copolymer of styrene and either or both of isoprene and butene.

4. The optical laminate according to claim 1,
wherein the film thickness of the cushioning layer is equal to or greater than 5 μm and equal to or smaller than 40 μm.

5. A front panel of an image display apparatus comprising:
the optical laminate according to claim 1.

6. An image display apparatus comprising:
the front panel according to claim 5; and
an image display device.

7. The image display apparatus according to claim 6,
wherein the image display device is a liquid crystal display device, an organic electroluminescence display device, an in-cell touch panel display device, or an on-cell touch panel display device.

8. A resistive film-type touch panel comprising:
the front panel according to claim 5.

9. A capacitance-type touch panel comprising:
the front panel according to claim 5.
